(19) United States
(12) Patent Application Publication
(10) Pub. No.: US 2012/0228013 A1
(43) Pub. Date: Sep. 13, 2012

(54) DEFECTIVE CONDUCTIVE SURFACE PAD REPAIR FOR MICROELECTRONIC CIRCUIT CARDS

(75) Inventors: Luis J. Matienzo, Endicott, NY (US); Susan Pitely, Vestal, NY (US); Norman A. Card, Lockwood, NY (US)

(73) Assignee: Endicott Interconnect Technologies, Inc., Endicott, NY (US)

(21) Appl. No.: 13/041,655

(22) Filed: Mar. 7, 2011

(51) Int. Cl. H05K 1/00; H01B 1/00; H01B 1/04; H05K 1/11; B23K 31/02; H01B 1/02; B82Y 30/00

(52) U.S. Cl. 174/258; 228/119; 252/500; 252/512; 252/514; 252/513; 252/502; 174/261; 977/773; 977/742; 977/762

(57) ABSTRACT

An electrically conductive adhesive (ECA) for repairing electrically conductive pad and trace interconnects and a method of repairing interconnect locations. The method of repairing at least one defect within the area of electrically conductive circuitized substrate traces and pads outside of a pristine center area incorporates an ECA and a forming gas plasma. The ECA contains a mixture of components that allow the adhesive to be adapted to specific requirements. Curing the adhesive results in effective electrical connections being formed between the adhesive and the base pad so that the metallurgies of the conductors and of the ECA are effectively combined to engage and repair the conductor defect.

### FIELD OF INVENTION

The present invention relates to defect repair using electrically conductive adhesive (ECA) and, more specifically, to an ECA that can be used to repair multiple, disparate interconnect locations, such as Z-interconnect surface pads, circuit board land areas, printed wiring board pads, circuitized substrate pads and the like.

### BACKGROUND OF THE INVENTION

Printed circuit boards (PCBs), chip carriers, and similar circuitized substrate products typically present one and often two opposing planar surfaces on which electronic components such as semiconductor chips, resistors, capacitors, modules, etc. are to be mounted. As known, PCBs may also have one or more chip carriers (each including one or more chips as part thereof) mounted thereon, while such chip carriers in turn may have the chips mounted to the substrates thereof, typically utilizing wire-bond or solder reflow technologies.

Circuit paths for these components are also typically provided by forming conductive lines, often referred to as traces, on the surfaces that often connect the conductors, sometimes referred to simply as pads, to thru-holes in the substrate. For component connections for which such thru-hole connections are not required, the conductive lines simply span between the conductors along the surface of the substrate. It is also known to connect the leads of such components directly to the thru-holes, i.e., to lands that surround same. By the term thru-holes as used herein is meant three types of conductive holes: a) those referred to as blind vias, which extend within part of the board from an outer surface (thus to a blind depth); b) internal vias which are located entirely within the board's structure (and thus covered by external layering); and c) holes that pass entirely through the board, also referred to in the printed circuit field as plated-thru-holes or PTHs. Such holes are usually formed by mechanical or laser drilling and then electroplating the internal surfaces with suitable conductive material, such as copper.

In the case of components with projecting metal leads (e.g., dual inline package (DIPs)), these leads are typically electrically connected to selected ones of the conductors using solder. Another form of connection involves the use of solder balls. One example involves using solder balls to directly couple contact sites (e.g., aluminum pads) of a chip to such pads, such as those on either a PCB or chip carrier, using conventional solder reflow processing. Solder balls are initially formed on the sites and then reflowed once positioned on the pads. One form of such reflow processing is referred to in the industry as controlled collapse chip connection (C4) processing. Thus, these solder balls serve as leads between the sites and pads in place of the metal members such as on DIPs, but in a different manner than the projecting leads of metal. Such solder connections are especially desirable in the industry to connect chips to substrates as well as chip carriers to PCBs, primarily due to the savings in substrate real estate. Such savings are extremely important in order to satisfy today's continuous demands for miniaturization.

PCBs and chip carriers made today often include several dielectric (e.g., a glass fiber-resin combination material known as FR-4) layers interspersed with the requisite number of conductive (e.g., copper) layers, which may be in the form of signal, power or ground layers. Other examples of the materials for both dielectric and conductive layers are provided hereinbelow. For such internal signal layers, the connecting lines thereof are also typically formed using the same processing as the external surface conductors and connecting lines, with the formed dielectric and conductor layers of this sub-composite then aligned and bonded to other sub-composites, typically using conventional lamination processes, to form the final multilayered composite structure.

PCBs and chip carriers are generally manufactured using either a subtractive etch process, a pattern plating process, or an electroless pattern plating process, also referred to as additive pattern plating. In all of these processes, a circuit mask that lays out the desired pattern of the conductive lines is transferred to the substrate by printing the circuit mask pattern onto a polymeric radiation-sensitive resist material, more simply referred to as photo-resist or, simply, as resist, deposited on the substrate surfaces. This resist material is irradiated in the pattern of the circuit mask so that it is physically transformed where it is irradiated and is unchanged where shielded by the circuit mask. The resist material is then developed by exposing it to a fast-reacting chemical solution that selectively removes either the irradiated material, called a positive resist, or removes the non-irradiated material, called a negative resist.

Subtractive etching typically begins with a substrate comprising a nonconductive dielectric material on which at least one layer of conductive material such as copper has been plated or laminated. A layer of photo-resist material is then deposited and developed in the circuit mask pattern so as to expose the conductive material where circuit paths are not desired. The exposed conductive material in the photo-resist voids is then etched away. Finally, the remaining photo-resist material is removed, leaving behind conductive lines wherever circuit paths were desired. The subtractive etch process provides good control over circuit path height because the amount of conductive material plated onto the substrate can generally be controlled very well. Precisely controlled circuit path height is especially important with surface mount techniques, especially when forming fine line circuitry with highly dense patterns.

Pattern plating, also referred to as acid plate pattern plating, uses electro-plating techniques to deposit conductive lines and pads in circuit paths defined by photo-resist material voids. More specifically, a conductive foil layer on the circuit board is connected to an electrode and the conductive material is deposited onto the board in the resist material voids using an oppositely charged electrode. The width of the conductive lines is generally dependent on the developed photo-resist pattern, which typically is of photographic sharpness. Pattern plating thereby provides good control over circuit path width and permits conductive lines of relatively fine width. The circuit path height, however, is not as easily controlled because such height is dependent on the density of the desired conductive lines. As a result, isolated conductive lines are typically thicker than densely packed (closely spaced) conductive lines. Thus, line height is sometimes not as precisely controlled by the acid plate process as may be desired, especially where higher densification is demanded.

Additive, or electroless, plating processing is similar to the acid plate pattern process, except that chemical plating processes are used rather than electro-plating processes. Additive plate fabrication generally requires more time to complete as compared to acid plate pattern fabrication but is typically not as susceptible to circuit path height variation according to line density. Additive plating may occasionally result in copper nodule formation, however, if not performed in a precise manner and under carefully controlled conditions.

Surfaces of substrates often need to be planarized during manufacture. Planarization methods such as surface machining remove non-planar regions of the board. Chemical mechanical polish, another often used method also employed in the semiconductor and ceramic industries, contains abrasive slurry materials which attack both resist and copper surfaces. Such polishing techniques are not compatible with many organic-based substrates, which are often used in conjunction with surface-mount technology substrates. Surface-mount technology utilizing solder ball connections as described above is popular today because it permits higher component densities and faster component mounting as compared with more conventional wire-bonding techniques in which it is necessary to electrically interconnect several small contacts and conductor sites with fine, delicate wires. Such polishing techniques are generally incompatible with organic based substrates because such substrates are somewhat flexible and typically have surface undulations. The surface undulations are due to variations in substrate thickness and also to the inherent flexibility of the substrates, which permits bowing and warping. Conventional chemical-mechanical polishing techniques do not follow these undulations and contours of flexible substrates. As a result, substrate areas of extra thickness or that bow outward are left with conductive lines having areas that are too thin, and board areas of reduced thickness are left with conductive lines having areas that are too thick.

As stated, conductive pads on the external surfaces of circuitized substrates mentioned hereinabove can also suffer from physical defects such as nicks, dents, and pin holes, or have exposed dielectric material within the copper plated areas. These types of defects can have an effect on the electrical connection and performance of the circuit board. In practice, these boards are generally deemed to be scrap. Board defect descriptions and criteria for surface mount lands defined in industry standard IPC—6012B sec. 3.5.4.2.1, and laminate defects defined in IPC—6012B sec. 3.3.2.7 are an example of criteria used for descriptions herein. IPC was formerly known as Institute for Interconnecting and Packaging Electronic Circuits, and consists of OEMs, board manufacturers, electronics manufacturing services companies and their suppliers. These defect issues are illustrated when complex boards having many fine pitch pads and lines have an inspection routine that looks for defects in the center pristine area of pads, as well as adjacent areas surrounding the pristine area. Typical scrap rates for this type of complex product may approach approximately 20%.

It is thus appreciated that in the manufacture and processing of circuitized substrates such as those defined above, it is essential to try to avoid the defects noted hereinabove, especially when producing products having highly dense circuit patterns. What is needed is a technique to repair such defects, while producing a compliant final substrate containing highly dense patterns of conductive pads and lines. The process should repair damaged pads with a conductive paste. This process should serve to repair pads damaged during manufacturing and/or subsequent processing, and repair defects or damage that normally would require the replacement of the entire substrate.

### DISCUSSION OF RELATED ART

U.S. Pat. No. 3,775,579 by Burghart et al., granted Nov. 27, 1973 for METHOD AND APPARATUS FOR REPAIRING PRINTED CIRCUITS discloses a method and apparatus for repairing an open or void in a printed circuit line on a printed circuit board wherein the board is positioned with the open underneath a bonding head and metallic ribbon material is positioned over the open, thermal compression bonded to the circuit line on one side of the open, cut to length, and then thermal compression bonded to the circuit line on the other side of the open.

U.S. Pat. Nos. 5,935,360 and 6,332,490 by Griggs, granted Aug. 10, 1999 and Dec. 25, 2001, for METHOD FOR REPAIRING A STRIP BONDED TO AN ARTICLE SURFACE and APPARATUS FOR BONDING A STRIP TO AN ARTICLE SURFACE, respectively, disclose a method for repairing a discrete damaged part of a strip bonded to an article surface. The steps include applying a first removable masking member along and adjacent the damaged part of the strip and separated from the strip by a gap of at least 0.005″, and applying a second removable masking member to the outer surface of the strip. A repair adhesive, which can be cured at a curing temperature less than a higher temperature that can result in damage to properties of the article or a surface coating, is applied at and beneath an edge of the damaged part of the strip. Then the repair adhesive is cured at the curing temperature. Apparatus for bonding a strip to an end portion of the article includes a body having a channel there through defined, in part, by spaced apart support surfaces for article surfaces and positioned relative one to the other at a relative spatial position substantially coinciding with the relative spatial position of the article surfaces. The support surfaces include surface profiles substantially reproducing surface profiles of the article surfaces.

U.S. Pat. No. 5,814,174 by Fong, granted Sep. 29, 1998 for METHOD FOR REPAIR OF METALLIZATION ON CIRCUIT BOARD SUBSTRATES discloses a method of repairing an area of metallization that has lifted from a circuit board substrate. A dry film epoxy is placed between the lifted metallization and the substrate. Downward pressure and heat are simultaneously applied to the lifted area to rebond it to the substrate. Both metallization pads and traces may be repaired with the method. When heated, the dry film epoxy will melt and cure very quickly, requiring no further processing. The method is useful when repairing circuit boards intended for microwave circuitry, in which conductive ribbons are gap welded to metallization pads. A metallization pad repair operation may be combined with a ribbon attachment operation, accomplishing both with one gap welding operation. The gap welder provides the downward force and heat necessary to bond the ribbon and repair the lifted pad.

U.S. Pat. No. 6,651,322 by Currie, granted Nov. 25, 2003 for METHOD OF REWORKING A MULTILAYER PRINTED CIRCUIT BOARD ASSEMBLY discloses a rework method and rework wiring structure for repairing and reworking multilayer printed circuit boards utilizing ball grid array (BGA) solder pads. The repair method includes the steps of locating a solder pad to be rewired, removing the identified pad, installing a repair wire through a via hole in a multilayer printed circuit board, and forming a replacement solder pad on the end of the repair wire and positioning it in place of the removed pad. Once thus installed, the method includes the step of connecting the other end of the repair wire to a corrected circuit interconnection point.

U.S. Pat. No. 5,391,516 by Wojnarowski, et al., granted Feb. 21, 1995 for METHOD FOR ENHANCEMENT OF SEMICONDUCTOR DEVICE CONTACT PADS discloses semiconductor device contact pads that are enhanced by forming a metal plate over at least a portion of the contact pad. Enhancement includes repair such as by bridging a reinforcing pad area over probe damage, general reinforcement or enlargement of a contact pad, and placement of a protective buffer pad over a contact pad. These methods are applicable to any semiconductor device with contact pads on a surface thereof, such as entire wafers, individual dice, and multi-chip High Density Interconnect (HDI) modules. The pad enhancement plate is formed by applying a planarizing dielectric layer over the entire device (if not already formed in the initial stages of HDI processing), and an enhancement access via is then formed to expose a portion of the contact pad to be enhanced. The entire device is metallized, and metal not over the exposed portion of the contact pad is subsequently removed. Localized heating of the metal plate can be achieved by a laser to effectuate a selective pseudo-weld or produce sintering for a low resistance ohmic contact.

U.S. Pat. No. 5,923,539 by Matsui, et al., granted Jul. 13, 1999 for MULTILAYER CIRCUIT SUBSTRATE WITH CIRCUIT REPAIRING FUNCTION, AND ELECTRONIC CIRCUIT DEVICE discloses a multilayer circuit substrate with a circuit repairing function which has a circuit substrate having a circuit pattern and repair pattern on the inner layer via an inter-substrate insulation film and having circuit repairing areas for cutting and bonding the circuit on these patterns, a terminal bonding pad for bonding electronic circuit parts mounted on this substrate, and a conductive via hole for bonding said circuit pattern to the terminal bonding pad, wherein at least the circuit repairing area of the repair pattern and at least the circuit repairing area of said circuit pattern which are set on said inner layer are brought close to each other and positioned on the same plane.

United States Published Patent Application No. 2008/0251289, by Palmeri et al, published Oct. 16, 2008 for DEVICE FOR REPAIR OF A CONTACT PAD OF A PRINTED CIRCUIT BOARD describes a method for repairing a damaged contact pad that is located on a first surface of a printed circuit board and connected to a via that passes through the circuit board. A countersink hole is created in the first surface of the printed circuit board in a location that is substantially centered on an axis passing through the via, and a replacement structure is inserted into the countersink hole. The replacement structure has a stem portion, a head portion, and a shoulder portion that connects the stem and head portions, with the angle of the shoulder portion substantially matching the angle of the shoulder of the countersink hole. The stem portion of the replacement structure is permanently attached to sidewalls of the via so as to electrically couple the head portion of the replacement structure to the via.

United States Published Patent Application No. 2009/0218696, by Jung et al, published Sep. 3, 2009 for SEMICONDUCTOR DEVICE INCLUDING A PADDING UNIT describes a semiconductor device including bit lines formed over a substrate and a padding unit formed over the bit lines. The padding unit includes stacked padding layers. A lower padding layer is formed between the bit lines and an upper padding layer. The upper layer as a slit formed therein. The lower padding layer prevents damage to the bit lines due to plasma gas entering through the slit.

United States Published Patent Application No. 2002/0166696, by Chamberlin et al, published Nov. 14, 2002 for LAND GRID ARRAY (LGA) PAD REPAIR STRUCTURE AND METHOD describes a method and structure to repair or modify a land grid array (LGA) interface mounted on a printed circuit card. The land grid array interface has a plurality of contact pads on a first surface of the printed circuit card, each contact pad is connected to at least one electronic component by a conductor. The method includes, for a preselected one of the contact pads to be replaced, drilling a first hole through printed circuit card at a predetermined location and having a first diameter predetermined to be sufficient to electrically isolate the preselected contact pad from all circuits contained in or on the printed circuit card. If any of the preselected contact pad or any conductor material directly attached to it remains attached to the first surface, it is delaminated, thereby separating it from the first surface of the printed circuit card. A preformed replacement conductor/contact pad structure is installed, such that one end of the structure having a replacement contact pad is positioned on the first surface of the printed circuit card at the location of the removed preselected contact pad. The second end of the replacement structure is electrically connected to at least one predetermined electronic component or layer, thereby completing the repair or modification.

The previously disclosed United States patents and published patent applications fail to apply conductive paste to repair and rebuild damaged and defective surface conductive traces and mounting pad locations, and to reduce rejection rates of complex circuit board contact structures having these defects. In fact, a number of the references utilize drilling the substrate as part of a multi-step process to accomplish what the present invention accomplishes in two steps: to repair the pad structure by applying ECA and curing the ECA.

Applicants use of a forming gas plasma consisting of a 10%-90% mix of H₂ and N₂, respectively, to condition any of the exposed copper or oxides present on the substrate, allows this newly conditioned surface to be amenable to the repair of plating.

It is therefore an object of the invention to utilize a combined approach to condition traces and pads using a forming gas plasma to create a surface that is amenable for application of an ECA to repair plating.

It is, therefore, also a primary object of the invention to enhance the art of circuitized substrate manufacture in which external conductors are repaired and rebuilt on the substrates and pass electrical inspection of connections formed thereon.

It is another object of the invention to provide such a method in which selected ones of the conductors are repaired or rebuilt with conductive adhesives.

It is still another object of the invention to provide such a process that can be carried out in a relatively expeditious manner using conventional processes and materials.

According to one embodiment of the invention, there is provided a method of making a circuitized substrate comprising providing a substrate including at least one dielectric layer having an external surface and a plurality of conductive traces and/or pads on this external surface, applying inspection standards to conductive locations, and for areas that fail inspection, repairing or rebuilding the traces and pads.

### SUMMARY OF THE INVENTION

According to the present invention, there is provided an electrically conductive adhesive (ECA) for the repair of surface layer traces and interconnect pad points. More specifically, the invention is applicable to situations in which a surface conductive location has failed inspection prior to being assembled into a laminate structure, and the defects are subsequently repaired or rebuilt to meet final product requirements for allowable damage or defect to traces or pads used in the creation of an electronic package or interlayer substrate interconnection.

### BRIEF DESCRIPTION OF THE DRAWINGS

A complete understanding of the present invention may be obtained by reference to the accompanying drawings, when considered in conjunction with the subsequent, detailed description, in which:

FIGS. 1 and 2 are top views showing pad defects that can occur during the making and processing of circuitized substrates; and

FIGS. 3 through 5 are sectional side views of steps performed during a defect repair in a pad land.

### DETAILED DESCRIPTION OF THE PREFERRED EMBODIMENT

Generally speaking, the present invention is a method and structure for repairing or rebuilding defective interconnect pads of substrate surfaces utilizing an electrically conductive adhesive (ECA). The connection repair or rebuild is achieved by disposing a quantity of ECA on the defective metallized surfaces. The use of an ECA on the defective connecting points enables the pad to pass physical and electrical inspection routines as an alternative to being scrapped.

For a better understanding of the present invention, together with other and further objects, advantages and capabilities thereof, reference is made to the following disclosure and appended claims.

By the term “circuitized substrate” as used herein is meant to define a structure including at least one dielectric layer having at least one surface having thereon at least one circuit. Examples of dielectric materials suitable for use in such structures include fiberglass-reinforced or non-reinforced epoxy resins (sometimes referred to simply as FR-4 material, meaning its Flame Retardant rating), polytetrafluoroethylene (Teflon), polyimides, polyamides, cyanate resins, photoimageable materials, and other like materials, or combinations thereof. Examples of electrically conductive materials for the circuit layers include copper or copper alloy. If the dielectric is a photoimageable material, it is photo-imaged or photo-patterned, and developed to reveal the desired circuit pattern, including the desired opening(s) as defined herein, if required. The dielectric material may be curtain coated or screen applied, or it may be supplied as a dry film or in other sheet form.

By the term “electroplating” as used herein is meant a process by which a metal in its ionic form is supplied with electrons to form a non-ionic coating on a desired substrate. The most common system involves: a chemical solution which contains the ionic form of the metal, an anode (positively charged) which may consist of the metal being plated (a soluble anode) or an insoluble anode (usually carbon, platinum, titanium, lead, or steel), and finally, a cathode (negatively charged) where electrons are supplied to produce a film of non-ionic metal.

By the term “electroless plating” (also known as chemical or auto-catalytic plating) as used herein is meant a non-galvanic type of plating method that involves several simultaneous reactions in an aqueous solution, which occur without the use of external electrical power. The reaction is accomplished when hydrogen is released by a reducing agent, normally sodium hypophosphite, and oxidized thus producing a negative charge on the surface of the part.

By the term “electronic package” as used herein is meant a circuitized substrate assembly as taught herein having one or more ICs (e.g., semiconductor chips) positioned thereon and electrically coupled thereto. In a multi-chip electronic package, for example, a processor, a memory device and a logic chip may be utilized and oriented in a manner designed for minimizing the limitation of system operational speed caused by long connection paths. Some examples of such packages, including those with a single chip or a plurality thereof, are also referred to in the art as chip carriers.

By the term “etch” and “etching” as used herein is meant a process by where a surface of a substrate is either selectively etched using a photoresist or covered by a mask prior to plasma treating, both methods are meant to transfer an image onto the substrate for subsequent further processing.

By the term “laser ablation” as used herein is meant the process of removing material from a solid surface by irradiating it with a laser beam. At low laser flux, the material is heated by the absorbed laser energy and evaporates or sublimes. At high laser flux, the material is typically converted to a plasma. The term laser ablation as used herein refers to removing material with a pulsed laser as well as ablating material with a continuous wave laser beam if the laser intensity is high enough.

By the term “solder-resist” as used here is meant to define a material able to protect circuitry and other parts of a substrate during the application of solder, including when the solder is applied in molten form (e.g., dipping the substrate within a molten solder “bath”). Such materials are comprised of resin formulations, permanent in nature, and generally green in color. These serve to encapsulate and protect the designated surface features of a substrate (except the specific areas where it is required to form solder joints), thereby preventing wetting by molten solder of all but those areas during assembly, while thereafter providing electrical insulation and protection against oxidation and corrosion. One method of creating the solder resist image is by stencil printing with a silk screen, but this technique often cannot achieve the precision of registration and resolution demanded by fine-pitch surface-mount designs; hence, liquid photo-imageable solder resist is now widely used in the industry for such high density features. These materials are available from many sources, including NEC, Tamura Kaken Corporation and Coates Circuits Products, to name a few. Because such companies are also well known in the industry, provision of the addresses thereof is also not deemed necessary.

As understood from the following, the present invention defines a unique method of providing for the repair of circuit pads on a substrate. As part of this method, selected ones of the resulting repaired conductors (pads) of the circuitry are modified in such a way as to pass required inspection criteria. The method is possible without the use of sophisticated and thus expensive equipment other than what is conventionally used in substrate manufacturing. It is thus attainable in a facile manner and at relatively low costs, compared to many processes known in the art.

By the term “thru-hole” as used herein to define an electrically conductive structure formed within a circuitized substrate as defined herein and is meant to include three different types of electrically conductive elements. It is known in multilayered PCB's and chip carriers to provide various conductive interconnections between various conductive layers of the PCB and carrier. For some applications, it is desired that electrical connection be made with almost if not all of the conductive layers. In such a case, thru-holes are typically provided through the entire thickness of the board, in which case these are often also referred to as “plated-thru-holes” or PTHs. For other applications, it is often desired to also provide electrical connection between the circuitry on one face of the substrate to a depth of only one or more of the inner circuit layers. These are referred to as “blind vias,” which pass only part way through (into) the substrate. In still another case, such multilayered substrates often require internal connections (“vias”) that are located entirely within the substrate and covered by external layering, including both dielectric and conductive. Such internal “vias,” also referred to as “buried vias,” may be formed within a first circuitized substrate that is then bonded to other substrates and/or dielectric and/or conductive layers to form the final, multilayered embodiment. Therefore, for purposes of this application, the term “thru-hole” is meant to include all three types of such electrically conductive openings.

According to one aspect of the invention, there is provided a method of repairing a circuitized substrate comprising one dielectric layer and at least one conductive layer including a plurality of metallic conductor pads as part thereof. The repair is accomplished by depositing a quantity of ECA, preferably, Ormet 7000 epoxy conductive paste, on a defective metallic conductor pad, curing the ECA using heat in such a manner that the metallurgies of the ECA and metallic conductor pads are combined to form an electrical connection therebetween, and restoring the geometry of the pad to the intended shape.

In semiconductor devices, electrically conducting adhesives are becoming more and more important as interconnecting materials and in the repair of circuit boards that have inherent surface mount pad defects or have had surface mount pads that have been damaged in handling or processing.

The present invention objective is to provide an ECA that can correct inherent defects or other pad damage issues to satisfy electrical and visual inspection requirement standards used in the microelectronics manufacturing industry, namely IPC-6012. Pastes can be composites of a polymer resin and conductive fillers with metal-to-metal bonding between conductive fillers and existing damaged pads to provide electrical conductivity and to land areas wherein the defect is diminished to within an acceptable percentage and the pristine area as defined in IPC-6012 is either preserved or enhanced.

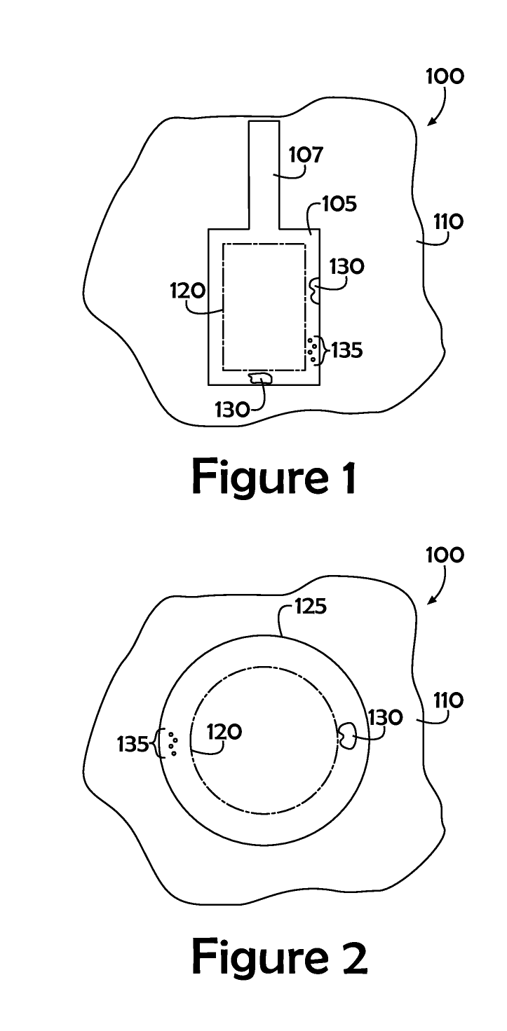

FIG. 1 is representative illustration of defects and/or damage that can occur on a substrate 100 during manufacture and subsequent processing. A conductive layer (not shown), preferably a copper sheet, is attached to a substrate 110 and etched creating a plurality of rectilinear pads 105 thereon. Although only one pad 105 is depicted in FIG. 1, this is meant to be representative only and the defects and repair described herein are also applicable to conductive traces 107. Pad 105, in the embodiment described here, is meant to form a land area on the finished substrate, such that conductive connections may be formed within the substrate assembly 110 or as an attachment point for soldering an electronic device in place. Pads and lands are known in the PCB art and further description is not deemed necessary. Pad 105 provides a conductive solder pad that may be used as a power, signal, or ground connection point for a local portion of the circuitized substrate of this invention.

Depicted in FIGS. 1 and 2 are defects that may arise during the manufacture and processing of the circuitized substrate. A pristine area 120, defined within specification IPC-6012 as the central 80% of both the rectangular 105 and circular 125 pad areas, may not have any nicks 130 or pinholes 135 encroach the pristine area 120. Nicks 130 and pinholes 135 are acceptable outside of the pristine area 120 to a certain percentage of total area, dependent upon the requirements of the manufacturer of the board. Also, an electrical test probe witness mark (not shown) is allowable within the pristine area 120.

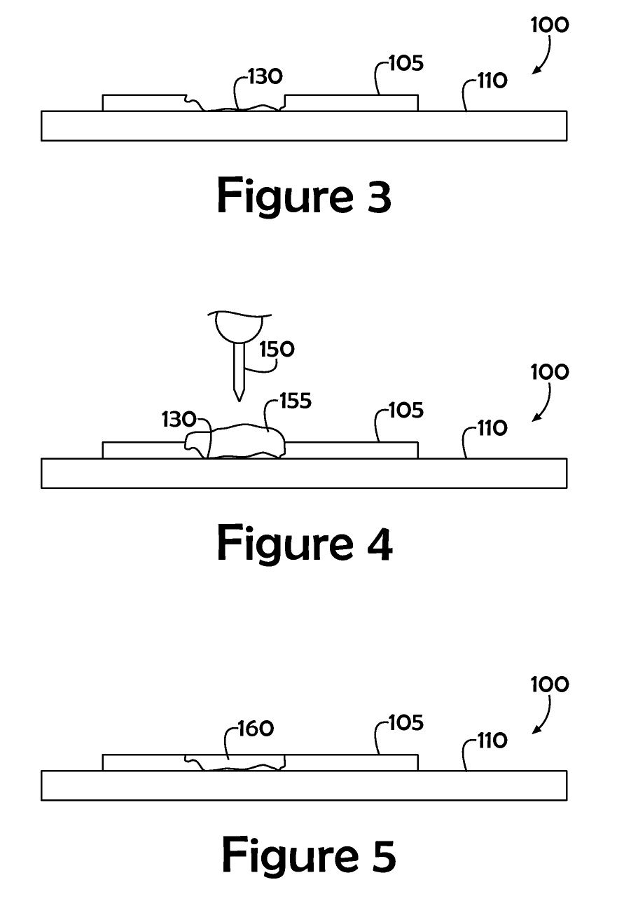

FIGS. 3 through 5 illustrate the repair of a defect and/or damage that has occurred on a substrate pad during manufacture or subsequent processing. In FIG. 3, the conductive layer (not shown) has been attached, by lamination or other means, to the substrate 110 and etched creating a pad 105 thereon. Nick 130 is shown outside of the pristine area 120 and is therefore acceptable to be repaired.

In FIG. 4, there is shown an electrically conductive adhesive 155 (ECA) dispensing tip 150 that has deposited a quantity of ECA 155 into nick 130 to fill the space created by the nick 130. ECA 155 may also be applied to the defect by hand, such as with an X-ACTO® knife or a fine point artist paintbrush (not shown).

After ECA 155 is cured 160, it is subjected to a forming gas plasma (not shown) consisting of a 10%-90% mix of H₂ and N₂, respectively, applied to the substrate 100 for approximately 15-18 minutes in a 250 mTorr atmosphere between room temperature and 60° C. to modify the surface of cured ECA 160 to reduce the oxidation potential of the metal in the paste if board 100 encounters a long wait time for re-inspection. The Ormet 7000 epoxy conductive paste, according to the manufacturer thereof, should be cured at 108° C. for 2 hours at ambient pressure. The board is then subjected to a visual and electrical re-inspection per product requirements. The plasma used is a relatively low temperature forming plasma, not high temperature reactive ion etch (RIE) plasma similar to one that generally removes photoresist. Alternatively, joining without plasma may be accomplished as a function of the lapse of time between surface preparation and joining. The complexity and density of the circuit boards that this process can be applied to currently has a reject rate approaching approximately 20%, and a reject at this point in the process results in a scrapped board.

Although the use of only one substrate layer has been described, it is understood that in the broadest aspects of this invention, more than one dielectric layer and conductive layers can be repaired, meaning that if the damage occurs later in the manufacturing process and a multi-layer board has been created, the outside surfaces of the stack can be repaired.

The function of the melted metallurgies (e.g., the solder particles of the ECA) is to provide an enhanced electrical connection through the paste in the final repaired structure.

The above repair, using conventional lamination equipment, may be accomplished at temperatures and pressures known in the art, and, as stated, serves to cure, sinter and melt, if appropriate, the adhesive compositions in the manner defined. The temperatures, times and pressures will likely be different for alternative materials, but still fall within the scope of the invention.

As explained above, the conductive adhesive functions as a conductive medium on the conductive pad of a designated dielectric layer (or layers). Such conductors may be formed using conventional photolithography processing, as mentioned, and serve as signal lines or pads for the layer-conductor subcomposite.

Adhesive curing can be performed using conventional methods, such as thermal, temperature-pressure, and UV/IR processes.

Since other combinations, modifications and changes varied to fit particular operating requirements and environments will be apparent to those skilled in the art, the invention is not considered limited to the chosen preferred embodiments for purposes of this disclosure, but covers all changes and modifications which do not constitute departures from the true spirit and scope of this invention.

Having thus described the invention, what is desired to be protected by Letters Patent is presented in the subsequently appended claims.

What is claimed is:

1. An electrically conductive adhesive (ECA) for repairing board level interconnects, comprising a conducting paste formulation containing a particle rich region.

2. The ECA of claim 1, wherein said electrically conductive adhesive formulation contains at least material chosen from the group: a low melting point alloy and a metal filler.

3. The ECA of claim 2, wherein said metal filler is chosen from the group: copper, silver, gold, zinc, cadmium, palladium, iridium, ruthenium, osmium, rhodium, platinum, iron, cobalt, nickel, indium, tin, antimony, lead, bismuth, and alloys thereof.

4. The ECA of claim 1, wherein said particle rich regions comprise an average particle size of approximately 1 micron to 20 microns for microparticles to approximately 20 nm to 300 nm for nanoparticles and can contain a mixture of micro and nanoparticles.

5. The ECA of claim 1, wherein said electrically conducting adhesive formulation comprises at least one solder chosen from the group: tin-lead, bismuth-tin, bismuth-tin-iron, tin, tin-silver, tin-gold, tin-silver-zinc, tin-silver-zinc-copper, tin-bismuth-silver, tin-copper, tin-copper-silver, tin-indium-silver, tin-antimony, tin-zinc, tin-zinc-indium, copper-based solders, and alloys thereof.

6. The ECA of claim 1, wherein said electrically conducting adhesive formulation comprises at least two components chosen from the group: polymer, metal particles, LMP alloy, carbon nanotubes, metal nanotubes, and mixtures thereof.

7. A method of repairing a circuitized substrate comprising:
providing a circuitized substrate including a plurality of metallic conductor pads as part thereof;
inspecting said plurality of metallic conductor pads such that each of said plurality of metallic conductor pads concomitantly undergoes pass/fail visual and electrical tests;
depositing a quantity of electrically conductive adhesive (ECA) on at least one of said failed inspected metallic conductor pads;
bonding said quantity of ECA to at least one of said failed metallic conductor pads using heat and pressure to combine the metallurgies of said ECA and said failed metallic conductor pads to form an electrical connection therebetween; and
exposing said quantity of bonded ECA to a forming gas plasma.

8. The method of claim 7, further including flowing said quantities of ECA after said depositing of said quantities thereof on said at least one of said failed metallic conductor pads.

9. The method of claim 8, wherein one of said failed conductor pads includes an ECA mixture layer thereon, a portion of said ECA mixture flowing at a predetermined temperature.

10. The method of claim 7, wherein said ECA comprises at least one metal chosen from the group: copper, silver, gold, zinc, cadmium, palladium, iridium, ruthenium, osmium, rhodium, platinum, iron, cobalt, nickel, indium, tin, antimony, lead, bismuth and alloys thereof.

11. The method of claim 7, wherein said ECA comprises at least one solder chosen from the group: tin-lead, bismuth-tin, bismuth-tin-iron, tin, tin-silver, tin-gold, tin-silver-zinc, tin-silver-zinc-copper, tin-bismuth-silver, tin-copper, tin-copper-silver, tin-indium-silver, tin-antimony, tin-zinc, tin-zinc-indium, copper-based solders, and alloys thereof.

12. The method of claim 7, wherein said ECA comprises at least two components chosen from the group: polymer, metal particles, LMP alloy, carbon nanotubes, metal nanotubes, and mixtures thereof.

13. The method of claim 7, wherein said ECA comprises at least one polymer chosen from the group: epoxy, Ormet epoxy, Ormet 7000 epoxy paste, silicones, and conducting polymers.

14. The method of claim 7, wherein said bonding process comprises at least one type chosen from the group: thermal, temperature-pressure, and UV/IR.

15. The method of claim 7, wherein said bonding of said ECA to said one of failed metallic conductor pads using said heat occurs for a time period of from approximately 0.5 minutes to approximately 120 minutes.

16. The method of claim 15, wherein said bonding occurs at a temperature within the range of from approximately 80° C. to approximately 180° C.

17. A circuitized substrate comprising:
at least two spaced-apart, electrically conductive pads having a pristine center area;
a plurality of organic dielectric spaces including first and second opposing surfaces, said second plurality of organic dielectric spaces positioned between said plurality of spaced-apart, electrically conductive pads;
at least one defect in said plurality of electrically conductive pads, bypassing said pristine center area;
a quantity of ECA positioned thereon said defect, said quantity of ECA including at least one metallic component including a plurality of particles and said quantity of ECA electrically coupled to said first plurality of spaced-apart electrically conductive pads;
at least one said defect having ECA positioned thereon having a plasma modified surface.

18. The circuitized substrate of claim 17, in which said plurality of organic dielectric layers are of a material selected from the following group: fiberglass-reinforced epoxy resin, polytetrafluoroethylene, polyimide, polyamide, cyanate resin, photo-imageable material, and combinations thereof.

19. The circuitized substrate of claim 17, wherein said quantity of ECA positioned on said defect further includes at least one of the group: solder particles as part thereof, an organic material, and a conducting polymer.

20. The circuitized substrate of claim 19, wherein said solder particle sizes are chosen from the group: microparticle and nanoparticle.

21. The circuitized substrate of claim 19, wherein said organic material comprises an epoxy resin.

22. The circuitized substrate of claim 17, wherein said quantity of plasma treated ECA positioned on said defect further includes a second metallic component having particles with sizes chosen from the group: microparticle and nanoparticle.
